(19) United States
(12) Patent Application Publication
(10) Pub. No.: US 2015/0313027 A1
(43) Pub. Date: Oct. 29, 2015

(54) ANTI-TAMPER DEVICE

(71) Applicant: HON HAI PRECISION INDUSTRY CO., LTD., New Taipei (TW)

(72) Inventors: SHENG-YEN LIN, New Taipei (TW); YING-JUI HUANG, New Taipei (TW)

(21) Appl. No.: 14/525,821

(22) Filed: Oct. 28, 2014

(30) Foreign Application Priority Data
Apr. 23, 2014 (TW) 103114608

(51) Int. Cl. H05K 5/02; H05K 5/00

(52) U.S. Cl. CPC H05K 5/0208; H05K 5/0013; H05K 5/0047

(57) ABSTRACT

An anti-tamper device for preventing data from being tampered with by an unauthorized person includes a top cover, a bottom cover, a printed circuit board (PCB), and a signal connector. The bottom cover is assembled to the top cover. The PCB has a plurality of terminal couplers. The signal connector is fastened to the top cover, and the signal connector defines a plurality of terminal grooves. At least one of the terminal grooves receives a terminal. When the terminals are electrically connected to the terminal couplers, a first relation signal is generated to enable the anti-tamper device. When the terminals are not connected to the corresponding terminal couplers, a second relation signal different from the first relation signal is generated by the PCB to make the anti-tamper device unable to work.

### FIELD

The subject matter relates to data protection technologies, and more particularly to an anti-tamper device.

### BACKGROUND

Electronic devices usually store confidential data such as account information in components of the electronic devices. In order to prevent an unauthorized person from accessing the components storing the confidential data, the components are located in a sealed housing. However, the housing of the electronic device must be able to be easily opened in order for a service repairman or technician to repair or replace any components when maintenance is required.

### BRIEF DESCRIPTION OF THE DRAWINGS

Implementations of the present technology will now be described, by way of example only, with reference to the attached figures.

FIG. 1 is a cross-sectional view of an anti-tamper device including a printed circuit board (PCB) and a signal connector.

FIG. 2 is an isometric view of the signal connector of FIG. 1.

FIG. 3 is an isometric view of the signal connector with a plurality of terminals.

FIG. 4 is an isometric view showing the signal connector separating from the PCB.

FIG. 5 is an isometric view showing the PCB with the terminals in a first embodiment.

FIG. 6 is an isometric view showing the PCB with the terminals in a second embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

The present disclosure is described in relation to an anti-tamper device 100.

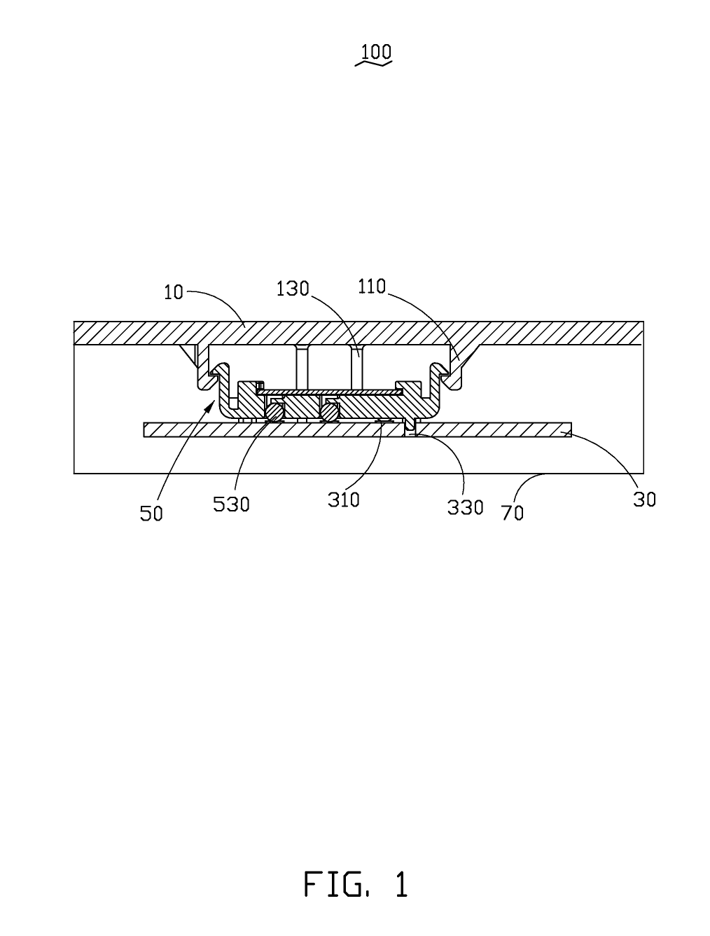

FIG. 1 illustrates a cross-sectional view of an anti-tamper device 100 for securing data. The anti-tamper device 100 can be a set-top box, router, a computer, or a portable device. The anti-tamper device 100 includes a top cover 10, a bottom cover 70, a printed circuit board (PCB) 30, and a signal connector 50. The top cover 10 is detachably coupled to the bottom cover 70 defining a receiving space for receiving the PCB 30 and the signal connector 50. The signal connector 50 is coupled to the top cover 10 and located between the top cover 10 and the PCB 30. When the top cover 10 is coupled to the bottom cover 70, the signal connector 50 makes contact with the PCB 30. When the top cover 10 is disengaged from the bottom cover 70, the signal connector 50 is separated from the PCB 30 synchronously.

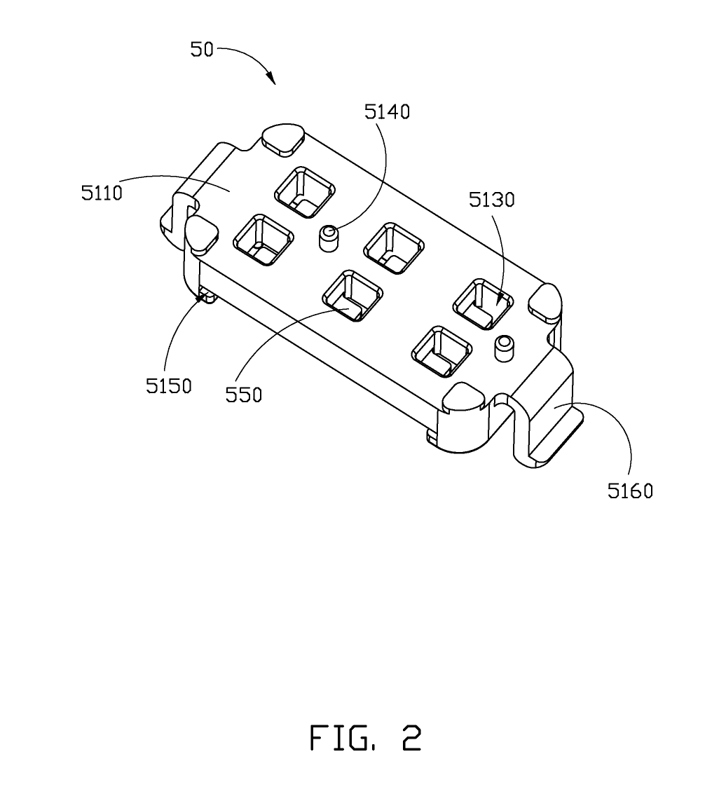

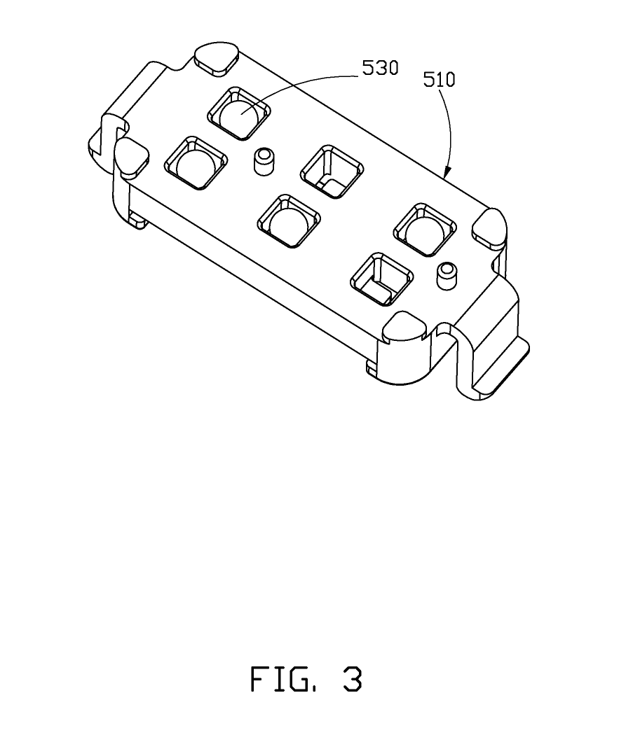

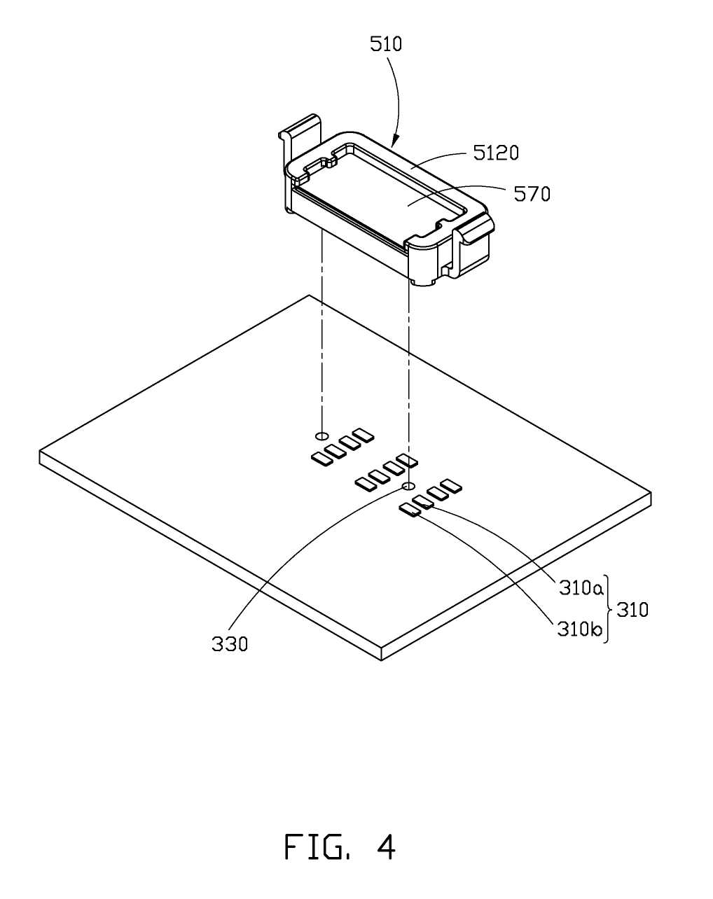

FIGS. 2, 3 and 4 illustrate that a bulge 130 and a pair of first clamps 110 both protrude from a surface of the top cover 10 facing the PCB 30 towards the bottom cover 70. The signal connector 50 includes a supporting base 510, a plurality of terminals 530 received in the supporting base 510, and a plurality of elastic pieces 550. The supporting base 510 is a rectangular board. The supporting base 510 includes a first surface 5110 and a second surface 5120 opposite to the first surface 5110, the first surface 5110 faces the PCB 30, and the second surface 5120 faces the top cover 10. A pair of second clamps 5160 protrudes from the supporting base 510 and is located at opposite ends of the supporting base 510. The supporting base 510 further defines a plurality of terminal grooves 5130 and a receiving groove 5150. The terminal grooves 5130 are defined in the first surface 5110. In at least one embodiment, the terminal grooves 5130 number six. Each of the elastic pieces 550 is located in a corresponding one of the terminal grooves 530. In at least one embodiment, each of the terminal grooves 5130 runs through the first surface 5110 and the second surface 5120. A locating protrusion 5140 protrudes from the first surface 5110 towards the PCB 30. The receiving groove 5150 is defined in the second surface 5120. In at least one embodiment, the receiving groove 5150 is communicating with the terminal grooves 5130. In other embodiments, the receiving groove 5150 is not communicating with the terminal grooves 5130. A magnet 570 is detachably received in the receiving groove 5150. The terminals 530 are received in the terminal grooves 5130 correspondingly. The terminals 530 received in the terminal grooves 5130 are attracted by the magnet 570 preventing the terminals 530 from falling out of the corresponding terminal groove 5130. In at least one embodiment, the terminals 530 are metal balls; a diameter of each terminal groove 5130 is larger than a diameter of the terminal 530, which allows the terminal 530 to move freely in the terminal groove 5130. In other embodiments, the terminals 530 can be metal columns. In at lest one embodiment, the terminals 530 number four. In other embodiments, the number of the terminals 530 can be more or less than four, but cannot exceed the number of the terminal grooves 5130.

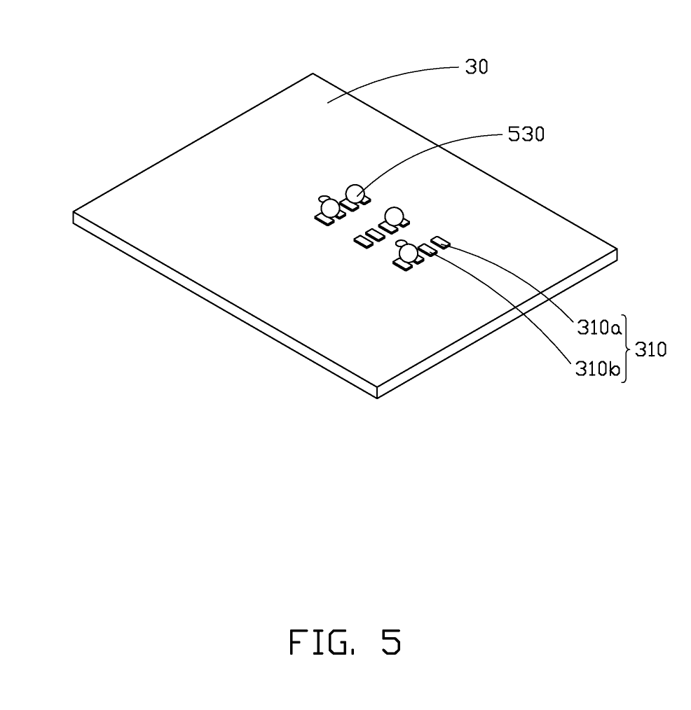

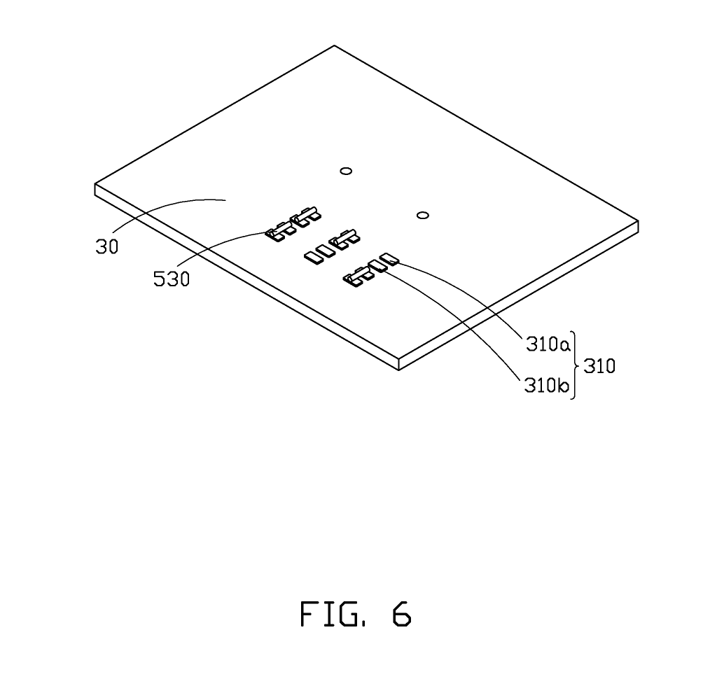

FIGS. 5 and 6 illustrate that a plurality of terminal couplers 310 are located on the PCB 30 corresponding respectively to the plurality of terminal grooves 5130. A locating hole 330 is defined in the PCB 30 corresponding to the locating protrusion 5140. In at least one embodiment, each of the terminal couplers 310 includes two metal pads 310a, 310b, and the two metal pads 310a, 310b are spaced from each other.

In assembly, first, the four terminals 530 are placed in the four of the six terminal grooves 5130; the four terminals 530 are attached to and held in the receiving groove 5150 by the magnet 570. Second, the locating protrusion 5140 is inserted into the locating hole 330 coupling with and preventing the signal connector 50 from moving relative to the PCB 30. The terminals 530 are pressed by the corresponding elastic pieces 550 to electrically couple to the corresponding terminal couplers 310. Third, the magnet 570 is detached from the receiving groove 5150. Fourth, the top cover 10 is coupled to the bottom cover 70, the first clamps 110 are engaged with the second clamps 5160 to fix the signal connector 50 to the top cover 10, and the bulge 130 blocks the second surface 5120 to limit a movement of the signal connector 50, at this time, the anti-tamper device 100 has been assembled. When the anti-tamper device is powered on for the first time after assembly, a first relative signal is generated by the PCB 30 to enable the anti-tamper device 100. The first relative signal indicates which terminal couplers 310 are electrically connected to the terminals, an original location relationship of the terminals 530 and the terminal grooves 5130. A memory device (not shown) on the PCB 30 is utilized to store the first relative signal.

When the top cover 10 is disengaged from the bottom cover 70 by an unauthorized person, the signal connector 50 is separated from the PCB 30 by the engagement of the first clamps 110 and the second clamps 5160, which cause the four terminals 530 to drop from the corresponding terminal grooves 5130 and disconnect from the terminal couplers 310. Because the terminals 530 drop from the terminal grooves 5130, the unauthorized person cannot put the terminals 530 back in the corresponding terminal grooves 5130. As a result, when the anti-tamper device 100 is assembled again as described above, a current location relationship between the terminals 530 and the terminal grooves 5130 will be different from the original location relationship described above. Furthermore, when the anti-tamper device 100 is powered on again after the reassembly, a second relation signal is generated for indicating the current location relationship between the terminals 530 and the terminal grooves 5130. The PCB 30 is utilized to compare the first relation signal to the second relation signal, when the second relation signal is different from the first relation signal; the PCB 30 disables the anti-tamper device 100.

With the anti-tamper device 100 described above, when an unauthorized person tries to manipulate data in the system by detaching the top cover 10 from the bottom cover 70, the terminals 530 drop from the corresponding terminal grooves 5130 which makes the unauthorized person unable to decide which terminal coupler 310 is electrically connected by the terminal 530. When the signal connector 50 is assembled to the PCB 30 and the terminals 530 are electrically connected to the terminal coupler 310 again, a second relation signal failing to conform to the first relation signal is generated to prevent the unauthorized person from operating the anti-tamper device 100.

Many details are often found in the art such as the other features of a shielding plate. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An anti-tamper device comprising:
a top cover;
a bottom cover detachably connected to the top cover;
a printed circuit board (PCB) fixed on the bottom cover, the PCB having a plurality of terminal couplers;
a signal connector fastened to the top cover and located between the PCB and the top cover, the signal connector defining a plurality of terminal grooves; and
a plurality of terminals, a number of the terminals being less than or equal to a number of the terminal grooves, the terminals being received in the terminal grooves correspondingly and electrically coupled to the terminal couplers correspondingly;
wherein when the top cover is disconnected from the bottom cover, the signal connector is separated from the PCB, and the terminals drop from the terminal grooves, when the top cover is connected to the bottom cover again and the terminals are not received in the terminal grooves correspondingly, the terminals are not electrically connected to the terminal couplers correspondingly and the anti-tamper device is unable to work.

2. The anti-tamper device of claim 1, wherein when the terminals are electrically connected to the corresponding terminal couplers, a first relative signal is generated by the PCB to enable the anti-tamper device; when the terminals are not connected to the corresponding terminal couplers, a second relative signal different from the first relative signal is generated by the PCB to make the anti-tamper device be out of work.

3. The anti-tamper device of claim 1, wherein the terminal grooves correspond respectively to the terminal couplers, when the terminals are received in the terminal grooves, the terminals are electrically connected to the terminal couplers corresponding the terminal grooves.

4. The anti-tamper device of claim 1, wherein a number of the terminals received in the corresponding terminal grooves is less than a number of the terminal grooves.

5. The anti-tamper device of claim 1, wherein the signal connector comprises a supporting base, the plurality of terminal grooves are defined in a first surface of the supporting base facing the PCB, a receiving groove is defined in a second surface of the supporting base opposite to the first surface, a magnet is located in the receiving grooves to attract the terminals received in the corresponding terminal grooves when the signal connector is coupled to the PCB, and the magnet is taken out of the receiving groove before the top cover is connected to the bottom cover.

6. The anti-tamper device of claim 5, wherein a pair of first clamps projects from the top cover towards the PCB, a pair of second clamps projects from the second surface of the supporting base towards the top cover, the second clamps are engaged with the first clamps to fix the signal connector to the top cover.

7. The anti-tamper device of claim 5, wherein at least one locating protrusion is located on the first surface, at lease one locating hole is defined in the PCB corresponding to the locating protrusion, and the locating protrusion is inserted into the locating hole to make the signal connector be coupled to the PCB.

8. The anti-tamper device of claim 1, wherein an elastic piece is located in each of the terminal grooves and between the terminal and the signal connector, and the elastic piece is compressed by the corresponding terminal and the signal connector when the top cover is connected to the bottom cover.

9. The anti-tamper device of claim 1, wherein each of the terminals is a metal ball which is movably received in the terminal groove.

10. The anti-tamper device of claim 1, wherein a number of terminal couplers is the same with a number of terminal grooves, each of the terminal couplers comprises two apart metal pads, and each of the terminals is electrically connected with the two metal pads.

11. An anti-tamper device comprising:
a top cover;
a bottom cover detachably assembled to the top cover;
a printed circuit board (PCB) received between the bottom cover and the top cover, the PCB having a plurality of terminal couplers; and
a signal connector fastened to the top cover and located between the PCB and the top cover, the signal connector defined a plurality of terminal grooves,
a first terminal groove of the terminal grooves receiving a terminal, and
a corresponding one of the terminal couplers being electrically connected to the terminal;
wherein when the top cover is disassembled from the bottom cover, the signal connector is separated from the PCB, and the terminal drops from the first terminal groove; when the top cover is assembled to bottom cover again and the dropped terminal is received in a second terminal groove of the terminal grooves, the corresponding terminal coupler is disconnected from the coupler, the anti-tamper device is out of work.

12. The anti-tamper device of claim 11, wherein the terminal grooves correspond to the terminal couplers, respectively, when the terminals are received in the terminal grooves, the terminals are electrically connected to the terminal couplers corresponding the terminal grooves.

13. The anti-tamper device of claim 11, wherein the signal connector comprises a supporting base, the plurality of terminal grooves are defined in a first surface of the supporting base facing the PCB, a receiving groove is defined in a second surface of the supporting base opposite to the first surface, a magnet is located in the receiving grooves to attract the terminals received in the corresponding terminal grooves when the signal connector is coupled to the PCB, and the magnet is taken out of the receiving groove before the top cover is connected to the bottom cover.

14. The anti-tamper device of claim 13, wherein a pair of first clamps projects from the top cover towards the PCB, a pair of second clamps projects from the second surface of the supporting base towards the top cover, the second clamps are engaged with the first clamps to fix the signal connector to the top cover.

15. The anti-tamper device of claim 14, wherein at least one locating protrusion is located on the first surface, at lease one locating hole is defined in the PCB corresponding to the locating protrusion, and the locating protrusion is inserted into the locating hole to make the signal connector be coupled to the PCB.

16. The anti-tamper device of claim 11, wherein an elastic piece is located in each of the terminal grooves and between the terminal and the signal connector, and the elastic piece is compressed by the corresponding terminal and the signal connector when the top cover is connected to the bottom cover.

17. The anti-tamper device of claim 11, wherein each of the terminals is a metal ball which is movably received in the terminal groove.

18. The anti-tamper device of claim 11, wherein a number of terminal couplers is the same with a number of terminal grooves, each of the terminal couplers comprises two apart metal pads, and each of the terminals is electrically connected with the two metal pads.
